(19) United States
(12) Patent Application Publication
(10) Pub. No.: US 2022/0343582 A1
(43) Pub. Date: Oct. 27, 2022

(54) APPLICATION OF DISPLACEMENT MAPS TO 3D MESH MODELS

(71) Applicant: Hewlett-Packard Development Company, L.P., Spring, TX (US)

(72) Inventors: Víctor ANTON DOMINGUEZ, Barcelona (ES); Joao Hugo BALLESTEROS BRANDÃO, Barcelona (ES); Antonio CHICA CALAF, Barcelona (ES); Pol MARTÍN GARCIA, Barcelona (ES); Konstantinos KAZATZIS, Barcelona (ES); Àlvaro VINACUA PLA, Barcelona (ES); Oriol GIRALT I GARCIA, Sant Cugat del Valles (ES); Alex CARRUESCO LLORENS, Sant Cugat del Valles (ES); Sergio GONZÁLEZ MARTIN, Sant Cugat del Valles (ES); Jordi GONZÁLEZ ROGEL, Sant Cugat del Valles (ES)

(73) Assignee: Hewlett-Packard Development Company, L.P., Spring, TX (US)

(21) Appl. No.: 17/236,905

(22) Filed: Apr. 21, 2021

(51) Int. Cl. G06T 15/04; G06T 17/20; G06T 15/00; G06F 30/23

(52) U.S. Cl. CPC G06T 15/04; G06T 17/20; G06T 15/005; G06F 30/23

(57) ABSTRACT

According to examples, machine-readable instructions may cause a processor to obtain a 3D mesh model of a part and to obtain a displacement map that defines amounts of displacements to be applied to various points in the 3D mesh model, in which the displacement map is at a first resolution. The processor may also generate a lower resolution version of the displacement map, in which the lower resolution is lower than the first resolution. The processor may further apply the lower resolution version of the displacement map on the 3D mesh model to generate an updated 3D mesh model.

### BACKGROUND

Three-dimensional (3D) fabrication systems may fabricate objects based on 3D models, such as 3D triangle mesh models, of the objects. The 3D models may include a plurality of data points, e.g., surfaces, vertices, etc. As there may be a large number of data points in the 3D models, the 3D models may have relatively large file sizes. Modification of the 3D models to include additional features may result in the 3D models having additional data points, which may increase their file sizes.

### BRIEF DESCRIPTION OF DRAWINGS

Features of the present disclosure are illustrated by way of example and not limited in the following figure(s), in which like numerals indicate like elements, in which:

FIG. 1 shows a block diagram of an example computer-readable medium that may have stored thereon computer-readable instructions for generating a lower resolution version of a displacement map and applying the lower resolution version of the displacement map onto a 3D mesh model;

FIG. 2 shows a diagram of an apparatus, which includes an example processor that may execute the computer-readable instructions stored on the example computer-readable medium depicted in FIG. 1;

FIG. 3 depicts an example diagram of a representative triangle from a UV-mapped version of a lower resolution version the 3D mesh model depicted in FIG. 2; and

FIGS. 4 and 5, respectively, depict flow diagrams of example methods for generating a lower resolution version of a displacement map and applying the lower resolution version of the displacement map onto a 3D mesh model to generate an updated 3D mesh model.

### DETAILED DESCRIPTION

For simplicity and illustrative purposes, the principles of the present disclosure are described by referring mainly to examples thereof. In the following description, numerous specific details are set forth in order to provide an understanding of the examples. It will be apparent, however, to one of ordinary skill in the art, that the examples may be practiced without limitation to these specific details. In some instances, well known methods and/or structures have not been described in detail so as not to unnecessarily obscure the description of the examples. Furthermore, the examples may be used together in various combinations.

Throughout the present disclosure, the terms “a” and “an” are intended to denote at least one of a particular element. As used herein, the term “includes” means includes but not limited to, the term “including” means including but not limited to. The term “based on” means based at least in part on.

Disclosed herein are computer-readable media, methods, and apparatuses for generating a lower resolution version of a displacement map and applying the lower resolution version of the displacement map on a 3D mesh model to generate an updated 3D mesh model. The displacement map may be a 2D array of displacement values that may be interpreted to modify in a positive or negative direction on a surface feature. In some instances, the displacement map may include grayscale values that correspond to various heights or depths from a certain reference plane. The application of the displacement map onto the 3D mesh model may add a 3D texture, such as a surface roughness, a 3D design, or the like, to the 3D mesh model. When the displacement map is applied onto the 3D mesh model, additional features that represent the 3D texture may be added to the 3D mesh model. In some examples, the 3D mesh model may be a 3D triangle mesh model that may include a plurality of triangles that represent the surface of the model. In these examples, the additional features may be additional triangles corresponding to the additional features.

In some instances, the displacement map may have a resolution that is greater than the resolution at which a 3D fabrication system is to use the 3D mesh model to fabricate a part. In these instances, the 3D fabrication system may be unable to fabricate the part at the same resolution as the displacement map. As a result, all of the additional features, e.g., the additional triangles, that may represent the 3D features from the displacement map may not be included in the fabricated part. As the size of a file storing the 3D mesh model may be affected by the number of features, e.g., triangles, in the 3D mesh model, a 3D mesh model including features that are not included in the fabricated part may waste storage space. In addition, a processor may unnecessarily utilize resources, e.g., computing resources, energy, storage space, etc., in processing, e.g., voxelizing, slicing, etc., the features that are not included in the fabricated part.

Through implementation of features of the present disclosure, a processor may reduce or eliminate the addition of unnecessary or extraneous features to a 3D mesh model. Particularly, the processor may generate a lower resolution version of a displacement map that has a resolution that is more closely matched to the resolution, e.g., voxel sizes, at which a 3D fabrication system fabricates parts. The processor may generate the lower resolution version by mipmapping (or anisotropically mipmapping), or equivalently, applying a mipmapping filter on, the displacement map. The application of the lower resolution version of the displacement map to the 3D mesh model may reduce extraneous features, e.g., features that are not formed or that are formed at a lower resolution than the displacement map, from being added to the 3D mesh model. A technical improvement afforded by the features of the present disclosure may thus be that storage space used to store the 3D mesh model may be reduced, which may reduce wasted space usage as well as computational resource usage in processing the 3D mesh model.

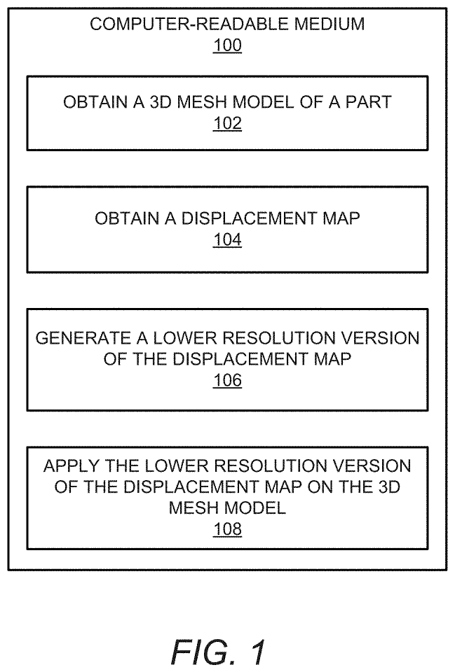

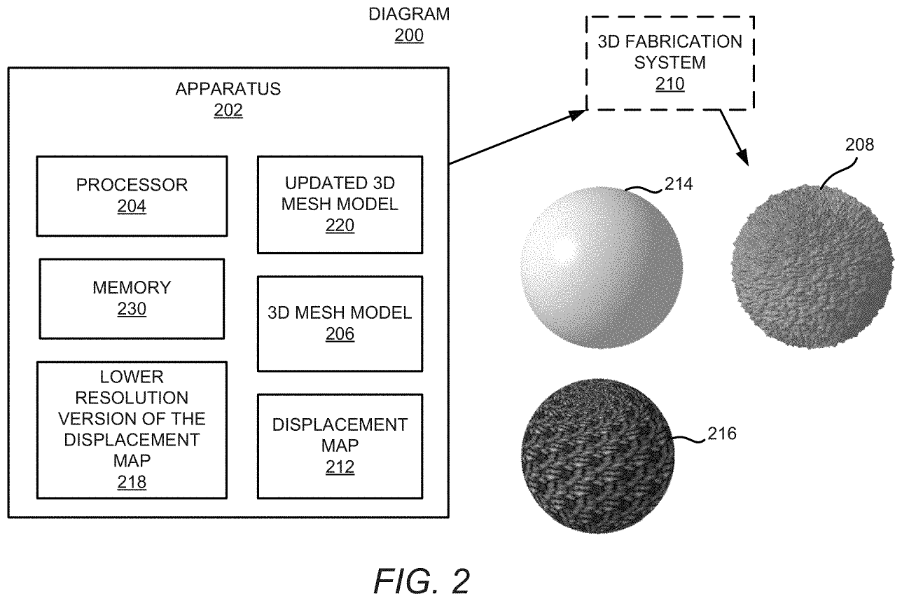

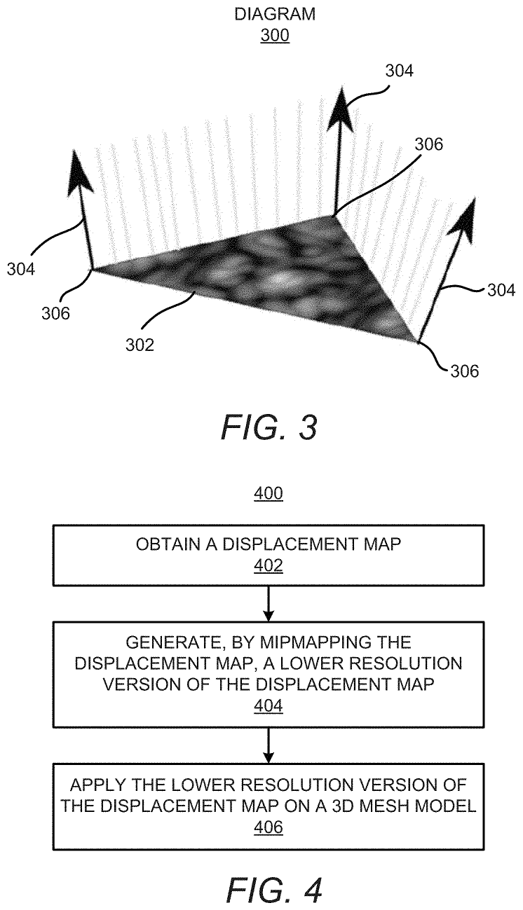

Reference is first made to FIGS. 1-3. FIG. 1 shows a block diagram of an example computer-readable medium 100 that may have stored thereon computer-readable instructions for generating and applying a lower resolution version of a displacement map onto a 3D mesh model. FIG. 2 shows a diagram 200 of an apparatus 202, which includes an example processor 204 that may execute the computer-readable instructions stored on the example computer-readable medium 100 depicted in FIG. 1. FIG. 3 depicts an example diagram of a representative triangle from a UV-mapped version of a lower resolution version the 3D mesh model depicted in FIG. 2. It should be understood that the computer-readable medium 100, the apparatus 202, and/or the diagram 300 may include additional features and that some of the features described herein may be removed and/or modified without departing from the scopes of the computer-readable medium 100, the apparatus 202, and/or the diagram 300 discussed herein.

The computer-readable medium 100 may have stored thereon computer-readable instructions 102-108 that a processor, such as the processor 204 depicted in FIG. 2, may execute. The computer-readable medium 100 may be an electronic, magnetic, optical, or other physical storage device that contains or stores executable instructions. The computer-readable medium 100 may be, for example, Random Access memory (RAM), an Electrically Erasable Programmable Read-Only Memory (EEPROM), a storage device, an optical disc, and the like. Generally speaking, the computer-readable medium 100 may be a non-transitory computer-readable medium, in which the term “non-transitory” does not encompass transitory propagating signals.

The processor 204 may fetch, decode, and execute the instructions 102 to obtain a 3D mesh model 206 of a part 208. The part 208 may be a 3D object that a 3D fabrication system 210 may fabricate based on a version of the 3D mesh model 206 as discussed herein. The 3D mesh model 206 may be a 3D computer model of the part 208, such as a computer aided design (CAD) file, a print-ready file (such as a 3D manufacturing format (3MF) file), and/or the like, or other types of digital representations of the part 208. The 3D mesh model 206 may be unique to a 3D fabrication system 210 as the 3D mesh model 206 may take into consideration the printing resolution of the 3D fabrication system 210.

Analogous to pixels in a picture image and texels in a texture image (such as a displacement map 212, 216 as discussed herein), the 3D mesh model 206 may include a 3D grid of volume pixels, which may be referred to as volume elements or voxels. In order to fabricate the part 208, the 3D fabrication system 210 may utilize the 3D mesh model 206 (or an updated 3D mesh model 220 as discussed herein). The voxels of the 3D mesh model 206 may, in some cases, be considered to be the fundamental fabrication unit of the 3D fabrication system 210. Therefore, the minimum size of a voxel may be referred to as the printing resolution of the 3D fabrication system 210. In some examples, the dimensions of a voxel may not be equal, e.g., the x, y, and/or z dimensions of the voxel may be different. Furthermore, the voxels of a 3D mesh model 206 may not have the same dimensions throughout the 3D mesh model 206.

In some examples, the 3D mesh model 206 may be a 3D triangle mesh model 206. In other words, the 3D mesh model 206 may include a set of triangles that may be connected to other triangles by their common edges and/or corners, in which the set of triangles may represent surfaces of the 3D mesh model 206. Generally speaking, the resolution of the 3D mesh model 206 may be increased through use of smaller triangles, but the amount of space in a file used to store the 3D mesh model 206 may also be increased to represent the increased number of triangles. Additionally, a greater number of triangles may be used to represent smoother curvatures and/or greater roughness elements on the surfaces of the 3D mesh model 206.

The processor 204 may fetch, decode, and execute the instructions 104 to obtain a displacement map 212. The displacement map 212 may define amounts of displacements to be applied to various points in the 3D mesh model 206. That is, the displacement map 212 may identify the heights above or depths below reference surface points at various locations on the 3D mesh model 206. The displacement map 212 may include grayscale values that correspond to the various heights or depths, in which different grayscale values may correspond to different heights or depths. The displacement map 212 may thus add texture, roughness, and/or a 3D design onto the surface of the 3D mesh model 206 and thus, to the part 208 fabricated from the 3D mesh model 206.

FIG. 2 shows graphical examples of a 3D mesh model 214 and a displacement map 216, which respectively correspond to the 3D mesh model 206 and the displacement map 212. As shown, the 3D mesh model 214 may include a relatively smooth surface. Although not explicitly shown in FIG. 2, the surface of the 3D mesh model 206, 214 may be formed of a certain number of triangles arranged in a mesh formation. As also shown, the displacement map 212, 216 may include grayscale values, in which the various colors may represent various heights or depths at various locations across the displacement map 212, 216.

In some instances, the displacement map 212, 216 may be at a first resolution that may be higher than a resolution at which the 3D fabrication system 210 may fabricate the part 208. In some cases, the resolution of the displacement map 212, 216 may be significantly higher than the resolution of the 3D fabrication system 210. According to examples, the processor 204 may fetch, decode, and execute the instructions 106 to generate a lower resolution version 218 of the displacement map 212, 216, in which the lower resolution version 218 has a resolution that is lower than the first resolution of the displacement map 212, 216.

For instance, the processor 204 may generate the lower resolution version 218 to have a predefined resolution level, which may be user-defined, correspond to a particular 3D fabrication system, correspond to a certain maximum file size, and/or the like. In a particular example, the processor 204 may generate the lower resolution version 218 to have a resolution that matches or is close to (e.g., within 10% deviation or less) of the resolution of the 3D fabrication system 210 that is to fabricate the part 208. Matching the resolution of the displacement map 212, 216 to the resolution of the 3D fabrication system 210, e.g., matching the sizes of the texels in the displacement map 212, 216 to the sizes of the voxels may reduce the number of triangles used to represent features identified in the displacement map 212, 216. As a result, the size of the file containing the 3D mesh model 206 upon which the displacement map 212, 216 is applied may be reduced.

Prior to a 3D fabrication process, the displacement map 212, 216 may be pre-processed to generate a selection of lower resolution versions 218 of the displacement map 212, 216. The lower resolution versions 218 may be evaluated to select an appropriate lower resolution version 218 that matches or falls below the predefined resolution level, e.g., the resolution level of the 3D fabrication system 210. For each voxel of the 3D mesh model 206, an appropriate lower resolution version 218 may be selected. For example, an appropriate lower resolution version 218 may be a displacement map 212, 216 where the size of the texel of the lower resolution version 218 is closest to the size of the voxel of the 3D mesh model 206 for the 3D fabrication system 210.

According to examples, the processor 204 may generate the lower resolution version (or versions) 218 of the displacement map 212, 216 by mipmapping the displacement map 212, 216. Or, equivalently, the processor 204 may apply a mipmapping filtering on the displacement map 212, 216. By way of example, the mipmapping filtering may produce lower resolution versions of the displacement map 212, 216 by averaging sub-regions of the displacement map 212, 216 in a pyramidal scheme. The mipmapping filtering may also allow for the dynamic selection of the adequate resolution at a certain point in time, e.g., depending on the size of the object in the image.

The process of generating isotropically lower resolution versions 218 may be referred to as mipmapping. Isotropically mipmapping lower resolution versions 218 creates lower resolution versions 218 with equal absolute dimensions in x, y, and z directions. The lower resolution versions 218 may be created whereby each successive lower resolution version 218 has half the resolution in the x and y dimensions than the previous version. In other words, each lower resolution version 218 has a resolution of ½² or ¼ than the previous version. In order to correctly mipmap the original displacement map 212, 216, the number of texels of the original displacement map 212, 216 in the x and y dimensions may be a power of two.

By way of particular example, an original displacement map 212, 216 may have, for example, dimensions or a resolution of 1024×1024. Mipmapping the original displacement map 212, 216 may produce a lower resolution version 218 of the displacement map 212, 216 with a resolution of 512×512. Similarly, this lower resolution version 218 may be further mipmapped to produce a lower resolution version 218 with a resolution of 256×256. This process may repeat, to create successive lower and lower resolution versions 218, e.g., 128×128, 64×64, 32×32, etc. The mipmapping process may repeat until a lower resolution version 218 with a resolution of 1×1 is produced, or the process may stop at a predefined resolution level, e.g., a resolution level of the 3D fabrication system 210.

Therefore, a selection of lower resolution versions 218 or, equivalently, a selection of displacement maps 212, 216 with larger sized texels, may be generated. For each voxel of the 3D mesh model 206, the most appropriate lower resolution version 218 may be selected, based on the size of the texel and the size of the voxel. The selected lower resolution version 218 may have the closest ratio of 1:1 for the size of the texel to the size of the voxel.

In some examples, the processor 204 may anisotropically mipmap the displacement map 212, 216. The process of generating anisotropically lower resolution versions 218 of the displacement map 212, 216 may be referred to as anisotropic mipmapping. Anisotropically mipmapping the displacement map 212, 216 may create lower resolution versions 218 with both equal and unequal dimensions in the x and y dimensions. The lower resolution versions 218 may be created whereby each successive lower resolution version 218 has half the resolution in the x and/or y dimension than the previous version 218.

By way of example, the original displacement map 212, 216 may have, for example a resolution of 1024×1024. Anisotropically mipmapping the original displacement map 212, 216 may produce lower resolution versions 218 with lower resolutions in the x dimension and in the y dimension. In some examples, the lower resolution versions 218 may be created with lower resolution versions with equal and unequal dimensions in the x and y dimensions, e.g., 1024×512, 1024×256, 512×512, 256×512, etc.

The process of anisotropic mipmapping may generate a selection of lower resolution versions 218 whereby the dimensions of the texels of the lower resolution versions 218 may not be equal in the x, y, and/or z dimensions. Therefore, for voxels with unequal dimensions in the x, y, and/or z dimension, the processor 204 may select an appropriate lower resolution version 218. For instance, the processor 204 may select the lower resolution version 218 in which the size of the texel in the lower resolution version 218 and the size of the voxel of the 3D fabrication system 210 are as equal (as close to the ratio 1:1) as possible.

In some examples, the processor 204 may determine whether the first resolution of the displacement map 212, 216 exceeds a predetermined resolution level. The predetermined resolution level may be equivalent to the predefined resolution level, e.g., the resolution level of the 3D fabrication system 210 or another predefined level. In these examples, the processor 204 may generate the lower resolution version 218 of the displacement map 212, 216 based on a determination that the first resolution exceeds the predetermined resolution level. In addition, the processor 204 may not generate the lower resolution version 218 of the displacement map 212, 216 based on a determination that the first resolution does not exceed the predetermined resolution level.

The processor 204 may fetch, decode, and execute the instructions 108 to apply the lower resolution version 218 of the displacement map 212, 216 on the 3D mesh model 206 to generate an updated 3D mesh model 220. In some examples in which multiple lower resolution versions 218 have been generated, the processor 204 may select the lower resolution version 218 that most closely matches the resolution of the 3D fabrication system 210 (e.g., the size of the voxel generated by the 3D fabrication system 210). The processor 204 may select the same lower resolution version 218 for each location of the 3D mesh model 206, 214 or may select various lower resolution versions 218 for different locations of the 3D mesh models 206, 214 based on sizes of the voxels at the locations of the 3D mesh model 206, 214.

The processor 204 may apply the selected lower resolution version 218 of the displacement map 212, 216 to the 3D mesh model 206, 214 to add texture to the 3D mesh model 206, 214. That is, for instance, the 3D mesh model 206, 214 may be UV-mapped to be in the two-dimensional (2D) space and the lower resolution version 218 of the displacement map 212, 216 may be applied, e.g., mapped, to the UV-mapped version of the 3D mesh model 206, 214. As discussed herein, the 3D mesh model 206 may have a relatively smooth surface represented by a mesh of triangles.

With reference to FIG. 3, there is shown an example diagram 300 of a representative triangle 302 from a UV-mapped version of the lower resolution version 218 of the 3D mesh model 206, 214. The processor 204 may generate the UV-mapped version of the lower resolution version 218 or the processor 204 may obtain the UV-mapped version from another source (not shown).

The triangle 302 may correspond to a region referenced by a certain set of UV coordinates in the UV-mapped version of the 3D mesh model 206. In the example depicted in FIG. 3, the processor 204 may determine normalized displacement vectors 304 at the vertices 306 of the triangle 252 from the displacement map 212, 216. The magnitudes of the displacement vectors 304 at the vertices 306 of the triangle 302 may correspond to the displacement values identified in the displacement map 212, 216 for the locations of the vertices 306. The processor 204 may also determine the displacements for the locations between the vertices 306 through implementation of any suitable interpolation operation on the displacement vectors 304. The processor 204 may make similar displacement magnitude determinations for the remaining triangles in the UV-mapped version of the lower resolution version 218.

In addition, the processor 204 may update the 3D mesh model 206 to include additional triangles corresponding to the determined displacement magnitude determinations of the triangles to generate the updated mesh model 220. That is, the updated mesh model 220 may be a 3D triangle mesh model having additional triangles that represent the texture identified in the lower resolution version 218 of the 3D mesh model 206, 214. The processor 204 may apply any suitable meshing technique to 3D mesh model 206 to generate the updated mesh model 220. The application of the lower resolution version 218 to the 3D mesh model 206 may result in a significantly fewer number of triangles than an application of the displacement map 212, 216 in an original resolution to the 3D mesh model 206. As a result, the file size of the updated 3D mesh model 206 may be significantly smaller than a file size of an updated 3D mesh model generated from the displacement map 212, 216 in its original resolution.

In any of the examples discussed herein, the 3D fabrication system 210 may fabricate the part 208 to include surface features as defined in the updated 3D mesh model 220. In some instances, a processor or controller of the 3D fabrication system 210 may control fabrication components (not shown) of the 3D fabrication system 210 to fabricate the part 208 using the updated 3D mesh model 220. In other instances, the processor 204 may control the fabrication components to fabricate the part 208 using the updated 3D mesh model 220. In either of these instances, the updated 3D mesh model 220 may undergo additional processes prior to being used for fabrication of the part 208, e.g., voxelization, slicing, and/or the like.

The 3D fabrication system 210 may be any suitable type of additive manufacturing system. Examples of suitable additive manufacturing systems may include systems that may employ curable binder jetting onto build materials (e.g., thermally or UV curable binders), ink jetting onto build materials, selective laser sintering, stereolithography, fused deposition modeling, etc. In a particular example, the 3D fabrication system 210 may form the part 208 by binding and/or fusing build material particles together. In any of these examples, the build material particles may be any suitable type of material that may be employed in 3D fabrication processes, such as, a metal, a plastic, a nylon, a ceramic, an alloy, and/or the like.

In some examples, the processor 204 may be part of an apparatus 202, which may be a computing system such as a server, a laptop computer, a tablet computer, a desktop computer, or the like. In other examples, the processor 204 may be part of the 3D fabrication system 210. In any of these examples, the processor 204 may be a semiconductor-based microprocessor, a central processing unit (CPU), an application specific integrated circuit (ASIC), a field-programmable gate array (FPGA), and/or other suitable hardware device. The apparatus 202 may also include a memory 230 that may have stored thereon computer-readable instructions (which may also be termed computer-readable instructions) that the processor 204 may execute. The memory 230 may be equivalent to the computer-readable medium 100 depicted in FIG. 1.

Although the apparatus 202 is depicted as having a single processor 204, it should be understood that the apparatus 202 may include additional processors and/or cores without departing from a scope of the apparatus 202. In this regard, references to a single processor 202 as well as to a single computer-readable medium 100 may be understood to additionally or alternatively pertain to multiple processors 204 and multiple memories 230. In addition, or alternatively, the processor 204 and the memory 230 may be integrated into a single component, e.g., an integrated circuit on which both the processor 204 and the memory 230 may be provided. In addition, or alternatively, the operations described herein as being performed by the processor 204 may be distributed across multiple apparatuses 202 and/or multiple processors 204.

By way of example, the memory 230 may have stored thereon instructions that when executed by the processor 204, may cause the processor 204 to obtain a 3D triangle mesh model 206, 214 of a part 208, to obtain a displacement map 212, 216 that defines amounts of displacements to be applied to various points in the 3D mesh model 206, 214, in which the displacement map 212, 216 is at a first resolution that is higher than a resolution at which a 3D fabrication system 210 is to fabricate the part 208. The instructions may also cause the processor 204 to generate a lower resolution version 218 of the displacement map 212, 216, in which the lower resolution version 218 corresponds to a predefined resolution level. The processor 204 may generate the lower resolution version 218 by anisotropically mipmapping the displacement map 212, 216 to cause the lower resolution version 218 to read the predefined resolution level. In addition, the instructions may cause the processor 204 to apply the lower resolution version 218 of the displacement map 212, 216 on the 3D triangle mesh model 206, 214 to generate an updated 3D triangle mesh model 220.

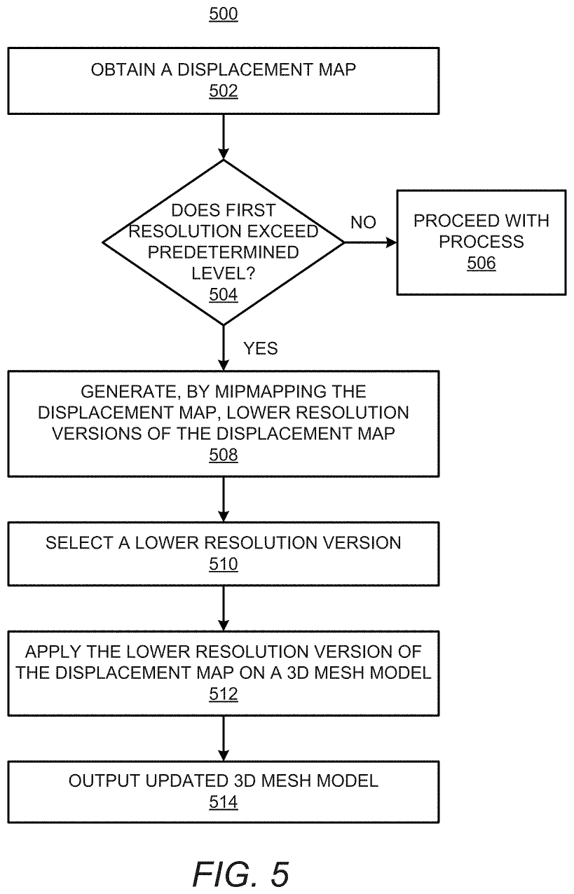

Various manners in which the processor 204 may operate are discussed in greater detail with respect to the methods 400 and 500 respectively depicted in FIGS. 4 and 5. Particularly, FIGS. 4 and 5, respectively, depict flow diagrams of example methods 400, 500 for generating and applying a lower resolution version 218 of a displacement map 212, 216 onto a 3D mesh model 206, 214 to generate an updated 3D mesh model 220. It should be understood that the example methods 400 and 500 may include additional operations and that some of the operations described herein may be removed and/or modified without departing from the scopes of the methods 400 and 500. The descriptions of the methods 400 and 500 are made with reference to the features depicted in FIGS. 1-3 for purposes of illustration.

With reference first to FIG. 4, at block 402, the processor 204 may obtain a displacement map 212, 216 that defines amounts of displacements to be applied to various points in a 3D mesh model 206, in which the displacement map 212, 216 is at a first resolution. As discussed herein, the displacement map 212, 216 may be at a resolution that is higher than a resolution of a 3D fabrication system 210 that is to fabricate a part 208 using the updated 3D mesh model 220.

At block 404, the processor 204 may generate, by mipmapping the displacement map 212, 216, a lower resolution version 218 of the displacement map 212, 216, in which the lower resolution version 218 is at a resolution level that is lower than the first resolution. As discussed herein, the processor 204 may generate the lower resolution version 218 (or multiple lower resolution versions 218) through mipmapping or through anisotropic mipmapping of the displacement map 212, 216.

At block 406, the processor 204 may apply the lower resolution version 218 of the displacement map 212, 216 on the 3D mesh model 206 to generate an updated 3D mesh model 220. The 3D fabrication system 210 may use the updated 3D mesh model 220 to fabricate the part 208.

Turning now to FIG. 5, at block 502, the processor 204 may obtain a displacement map 212, 216 that defines amounts of displacements to be applied to various points in a 3D mesh model 206, in which the displacement map 212, 216 is at a first resolution. The processor 204 may also obtain the 3D mesh model 206. The processor 204 may obtain, or equivalently, receive, download, access, or the like, the displacement map 212, 216 and/or the 3D mesh model 206 from any suitable source, e.g., a data store that may be local to the apparatus 202 or that the apparatus 202 may access via a network, such as the Internet.

At block 504, the processor 204 may determine whether the first resolution of the displacement map 212, 216 exceeds a predetermined resolution level. The predetermined resolution level may be the printing resolution (e.g., voxel size) of the 3D fabrication system 210. Based on a determination that the first resolution of the displacement map 212, 216 does not exceed the predetermined resolution level, at block 506, the processor 204 may proceed with processing the 3D mesh model 206, 214 and the displacement map 212, 216. That is, for instance, the processor 204 may apply the displacement map 212, 216 to the 3D mesh model 206 without lowering the resolution of the displacement map 212, 216.

However, based on a determination that the first resolution exceeds the predetermined resolution level, at block 508, the processor 204 may generate, by mipmapping, anisotropically mipmapping, etc., lower resolution versions 218 of the displacement map 212, 216. As discussed herein, the lower resolution versions 218 may be generated to have varying resolutions with respect to each other.

At block 510, the processor 204 may select one of the generated lower resolution versions 218 to be applied to the 3D mesh model 206. For instance, the processor 204 may select the lower resolution version 218 that most closely matches the resolution of the 3D fabrication system 210. In some examples, such as when the 3D fabrication system 210 prints at multiple voxel sizes, the processor 204 may select multiple ones of the lower resolution versions 218 that most closely match the multiple voxel sizes.

At block 512, the processor 204 may apply the selected lower resolution version 218 or versions 218 of the displacement map 212, 216 on the 3D mesh model 206 to generate an updated 3D mesh model 220. The application of the lower resolution version 218 may result in additional triangles being meshed into the 3D mesh model 206, in which the additional triangles may represent the features identified in the displacement map 212, 216. However, this may result in a smaller number of triangles being added into the 3D mesh model 206, 214 as compared with application of the displacement map 212, 216 at the first resolution onto the 3D mesh model 206, 214.

At block 514, the processor 204 may output the updated 3D mesh model 220 to the 3D fabrication system 210. In some examples, the processor 204 may prepare the updated 3D mesh model 220 for the 3D fabrication system 210 to use in fabricating the part 208. For instance, the processor 204 may voxelize the updated 3D mesh model 220, may generate slices from the updated 3D mesh model 220, and/or the like. In some examples, such as when the processor 204 is part of the 3D fabrication system 210, the processor 204 may control fabrication components in the 3D fabrication system 210 to fabricate the part 208.

Some or all of the operations set forth in the methods 400 and 500 may be included as utilities, programs, or subprograms, in any desired computer-accessible medium. In addition, the methods 400, 500 may be embodied by computer programs, which may exist in a variety of forms both active and inactive. For example, they may exist as machine-readable instructions, including source code, object code, executable code or other formats. Any of the above may be embodied on a non-transitory computer readable storage medium.

Examples of non-transitory computer readable storage media include computer system RAM, ROM, EPROM, EEPROM, and magnetic or optical disks or tapes. It is therefore to be understood that any electronic device capable of executing the above-described functions may perform those functions enumerated above.

Although described specifically throughout the entirety of the instant disclosure, representative examples of the present disclosure have utility over a wide range of applications, and the above discussion is not intended and should not be construed to be limiting, but is offered as an illustrative discussion of aspects of the disclosure.

What has been described and illustrated herein is an example of the disclosure along with some of its variations. The terms, descriptions and figures used herein are set forth by way of illustration only and are not meant as limitations. Many variations are possible within the scope of the disclosure, which is intended to be defined by the following claims—and their equivalents—in which all terms are meant in their broadest reasonable sense unless otherwise indicated.

1. A non-transitory computer-readable medium storing machine-readable instructions that when executed by a processor, cause the processor to:
obtain a three-dimensional (3D) mesh model of a 3D part;
obtain a displacement map that defines amounts of displacements to be applied to the 3D mesh model to add texture to a surface of the 3D mesh model, wherein the displacement map has a first resolution that is higher than a resolution corresponding to a system resolution at which a 3D fabrication system is to fabricate the 3 part;
generate a lower resolution version of the displacement map, wherein the lower resolution version has a predefined resolution that is lower than the first resolution of the displacement map and corresponds to a resolution that matches the system resolution at which the 3D fabrication system is to fabricate the 3D part, and wherein, at the predefined resolution of the lower resolution version, a size of a texel of the lower resolution version matches a size of an area unit corresponding to a voxel of the 3D mesh model for the 3D fabrication system; and
apply the lower resolution version of the displacement map on the 3D mesh model to generate an updated 3D mesh model, wherein the 3D fabrication system is to use the updated 3D mesh model to fabricate the 3D part.

2. The non-transitory computer-readable medium of claim 1, wherein, to generate the lower resolution version of the displacement map, the instructions further cause the processor to:
generate a plurality of lower resolution versions of the displacement map; and
select one of the plurality of lower resolution versions of the displacement map to be the lower resolution version that has the predefined resolution corresponding to a resolution that matches the system resolution.

3. The non-transitory computer-readable medium of claim 1, wherein the instructions further cause the processor to:
generate the lower resolution version of the displacement map by mipmapping the displacement map.

4. The non-transitory computer-readable medium of claim 1, wherein the instructions further cause the processor to:
generate the lower resolution version of the displacement map by iteratively mipmapping the displacement map until the lower resolution version reaches the predefined resolution.

5. The non-transitory computer-readable medium of claim 1, wherein the instructions further cause the processor to:
generate the lower resolution version of the displacement map by anisotropically mipmapping the displacement map to cause the lower resolution version of the displacement map to reach the predefined resolution.

6. (canceled)

7. The non-transitory computer-readable medium of claim 1, wherein the 3D mesh model comprises a 3D triangle mesh model and wherein the instructions further cause the processor to:
apply the lower resolution version of the displacement map on the 3D triangle mesh model to add triangles corresponding to the displacements defined in the lower resolution version of the displacement map to a surface of the 3D triangle mesh model.

8. The non-transitory computer-readable medium of claim 1, wherein the instructions further cause the processor to:
voxelize the updated 3D mesh model, wherein the 3D fabrication system is to fabricate the 3D part based on the voxelized updated 3D mesh model.

9. A method comprising:
obtaining, by a processor, a three-dimensional (3D) mesh model of a 3D part;
obtaining, by the processor, a displacement map that defines amounts of displacements to the 3D mesh model to add texture to a surface of the 3D mesh model, wherein the displacement map has a first resolution that is higher than a resolution corresponding to a system resolution at which a 3D fabrication system is to fabricate the 3 part;
generating, by the processor, a lower resolution version of the displacement map, wherein the lower resolution version has a predefined resolution that is lower than the first resolution of the displacement map and corresponds to a resolution that matches the system resolution at which the 3D fabrication system is to fabricate the 3D part, and wherein, at the predefined resolution of the lower resolution version, a size of a texel of the lower resolution version matches a size of an area unit corresponding to a voxel of the 3D mesh model for the 3D fabrication system; and
applying, by the processor, the lower resolution version of the displacement map on the 3D mesh model to generate an updated 3D mesh model, wherein the 3D fabrication system is to use the updated 3D mesh model to fabricate the 3D part.

10. The method of claim 9, wherein generating the lower resolution version of the displacement map comprises:
generating a plurality of lower resolution versions of the displacement map; and
selecting one of the plurality of lower resolution versions of the displacement map to be the lower resolution version that has the predefined resolution corresponding to a resolution that matches the system resolution.

11. The method of claim 9, wherein generating the lower resolution version of the displacement map further comprises:
generating the lower resolution version of the displacement map by anisotropically mipmapping the displacement map to cause the lower resolution version of the displacement map to reach the predefined resolution.

12. The method of claim 9, wherein the 3D mesh model comprises a 3D triangle mesh model and wherein the method further comprises:
applying the lower resolution version of the displacement map on the 3D triangle mesh model to add triangles corresponding to the displacements defined in the lower resolution version of the displacement map to a surface of the 3D triangle mesh model.

13. (canceled)

14. An apparatus comprising:
a processor, and
a memory storing instructions that when executed by the processor, cause the processor to:
obtain a three-dimensional (3D) mesh model of a 3D part;
obtain a displacement map that defines amounts of displacements to be applied to the 3D mesh model to add texture to a surface of the 3D mesh model, wherein the displacement map has a first resolution that is higher than a resolution corresponding to a system resolution at which a 3D fabrication system is to fabricate the 3D part;
generate a lower resolution version of the displacement map, wherein the lower resolution version has a predefined resolution that is lower than the first resolution of the displacement map and corresponds to a resolution that matches the system resolution at which the 3D fabrication system is to fabricate the 3D part, and wherein, at the predefined resolution of the lower resolution version, a size of a texel of the lower resolution version matches a size of an area unit corresponding to a voxel of the 3D mesh model for the 3D fabrication system; and
apply the lower resolution version of the displacement map on the 3D mesh model to generate an updated 3D mesh model, wherein the 3D fabrication system is to use the updated 3D mesh model to fabricate the 3D part.

15. The apparatus of claim 14, wherein to generate the lower resolution version of the displacement map, the instructions cause the processor to:
generate the lower resolution version of the displacement map by anisotropically mipmapping the displacement map to cause the lower resolution version of the displacement map to reach the predefined resolution.
